(19) United States
(12) Patent Application Publication
(10) Pub. No.: US 2016/0035965 A1
(43) Pub. Date: Feb. 4, 2016

(54) PZT-BASED PIEZOELECTRIC CERAMIC MATERIAL AND PIEZOELECTRIC DEVICE USING THE SAME

(71) Applicant: SAMSUNG ELECTRO-MECHANICS CO., LTD., Gyeonggi-Do (KR)

(72) Inventors: Yun Sung KANG, Gyeonggi-Do (KR); Seung Mo LIM, Gyeonggi-Do (KR); In Young KANG, Gyeonggi-Do (KR); Jeong Suong YANG, Gyeonggi-Do (KR)

(73) Assignee: SAMSUNG ELECTRO-MECHANICS CO., LTD., Gyeonggi-Do (KR)

(21) Appl. No.: 14/591,706

(22) Filed: Jan. 7, 2015

(30) Foreign Application Priority Data
Jul. 31, 2014 (KR) 10-2014-0098536

(51) Int. Cl. H01L 41/187

(52) U.S. Cl. CPC H01L 41/1876

(57) ABSTRACT

Embodiments of the invention provide a PZT-based piezoelectric ceramic material represented by the following formula: Pbx(ZryTiz)M1-y-zO3, which is an ABO3 perovskite crystal material including a crystal lattice A-site and a crystal lattice B-site, x, y, and z satisfying the following Equations, respectively: 0.830≦x≦0.964, 0.43≦y≦0.55, and 0.43≦z≦0.55, and M being a metal element having a valence of +5 or +6, and a piezoelectric device using the same. According to at least one embodiment, since Pb is not excessively added, a Pb or PbO phase deteriorating piezoelectric properties is not formed in a PZT-based piezoelectric material, such that excellent electric, dielectric, and piezoelectric properties are exhibited.

### CROSS REFERENCE TO RELATED APPLICATION

This application claims the benefit of and priority under 35 U.S.C. §119 to 35 U.S.C. §119 to Korean Patent Application No. KR 10-2014-0098536, entitled “PZT-BASED PIEZOELECTRIC CERAMIC MATERIAL AND PIEZOELECTRIC DEVICE USING THE SAME,” filed on Jul. 31, 2014, which is hereby incorporated by reference in its entirety into this application.

### BACKGROUND

1. Field of the Invention

The present invention relates to a lead zirconate titanate (PZT)-based piezoelectric ceramic material and a piezoelectric device using the same.

2. Description of the Related Art

Recently, importance of a piezoelectric thin film has been spotlighted for utilization as various devices that have become light and slim and had a small size such as a micro electromechanical system (MEMS), for example. Particularly, lead zirconate titanate (PZT) has been currently applied and studied in various fields, such as various sensors, switches, resonators, and memory devices, as non-limiting examples, due to excellent ferroelectric properties, remanent polarization, and piezoelectric properties. When a PZT-based piezoelectric material forms a perovskite structure represented by ABO₃, piezoelectric properties are exhibited. The perovskite structure is a structure that may be obtained only when a composition of the PZT-based piezoelectric material accurately corresponds to stoichiometry. Generally, since lead (Pb) has a tendency to be relatively easily volatilized due to a low melting point, at the time of preparing the PZT-based piezoelectric material, in consideration this tendency, extra Pb (10 to 50%) is added in order to maintain stoichiometry. However, this extra Pb is not entirely consumed but locally remains in the PZT-based piezoelectric material as a Pb or PbO phase, such that the remaining extra Pb finally serves as a main cause of decreasing breakdown voltage or deteriorating dielectric/piezoelectric properties.

In order to allow PZT to have the piezoelectric properties, a perovskite crystal structure should be formed. To this end, in Pbₓ(Zr_{y}Ti_{1-y})O₃, x and y, which are stoichiometric ratios, should satisfy the following Equations, respectively: 1≦x≦1.3 and 0.1≦y≦0.9. Here, in the case in which a composition ratio of Pb is less than 1, since the perovskite crystal structure may not be formed, but a fluorite or pyrochlore crystal structure is formed, asymmetry of a B-site is lost, such that the piezoelectric properties are not exhibited. In order to solve this problem, generally, at the time of preparing PZT, the perovskite structure is formed by adding an excessive amount of Pb to allow a final composition to correspond to stoichiometry. However, the excessively contained Pb remains in a form of a metal or oxide (PbO), thereby deteriorating properties of final PZT. Since it is impossible to control an accurate composition ratio of Pb, in spite of the above-mentioned disadvantage, Pb is added more than necessary.

Meanwhile, a piezoelectric device including a piezoelectric thin film containing Pb improving durability without deteriorating piezoelectric properties has been disclosed, for example, in the Japanese Patent Publication No. 2010-034448. In addition, a micro transformer capable of having large electro-mechanical coupling factor and mechanical quality factor, a high Curie temperature, decreasing self-heating due to vibration, and having high mechanical strength by adding elements such as Mn, Sb, and Nb to PZT-based ceramics and adjusting molar ratios thereof, and a sintering method thereof are disclosed, for example, in Korean Patent Publication No. 2001-0067818.

### SUMMARY

Accordingly, embodiments of the invention have been made to provide a piezoelectric ceramic material capable of maintaining excellent dielectric and piezoelectric properties by forming a stable perovskite crystal structure even through a composition ratio of lead (Pb) positioned at an A-site is less than 1 by adding a metal element having a valence of +5 or +6 to replace B-site elements.

Further, embodiments of the invention provide a piezoelectric device using a piezoelectric ceramic material capable of maintaining excellent dielectric and piezoelectric properties by forming a stable perovskite crystal structure even through a composition ratio of lead (Pb) positioned at an A-site is less than 1 by adding a metal element having a valence of +5 or +6 to replace B-site elements.

According to at least one embodiment of the invention, there is provided a PZT-based piezoelectric ceramic material including an ABO₃ perovskite crystal structure having a crystal lattice A-site and a crystal lattice B-site and is represented by the following formula: Pbₓ(Zr_{y}Ti_{z})M_{1-y-z}O₃, wherein x, y, and z satisfy the following Equations, respectively: 0.830≦x≦0.964, 0.43≦y≦0.55, and 0.43≦z≦0.55, and M is an element having a valence of +5 or +6.

According to at least one embodiment, M is at least one metal element selected from the group consisting of V, Nb, Sb, Ta, and W.

According to at least one embodiment, M is Nb.

According to at least one embodiment, M is Ta.

According to at least one embodiment, 12 to 14 at % of Nb is doped therein.

According to at least one other embodiment of the invention, there is provided a piezoelectric device including a substrate; a lower electrode formed on one surface of the substrate; a piezoelectric thin film formed on the lower electrode; and an upper electrode formed on the piezoelectric thin film; wherein the piezoelectric thin film is manufactured using a PZT-based piezoelectric ceramic material having an ABO₃ perovskite crystal structure and represented by the following formula: Pbₓ(Zr_{y}Ti_{z})M_{1-y-z}O₃, x, y, and z satisfying the following Equations, respectively: 0.830≦x≦0.964, 0.43≦y≦0.55, and 0.43≦z≦0.55, and M being an element having a valence of +5 or +6.

According to at least one embodiment, the piezoelectric thin film is formed by a radio-frequency sputtering method.

According to at least one embodiment, the substrate is a semiconductor substrate made of silicon (Si) or tungsten (W), or a heat resistance stainless steel (SUS) substrate.

According to at least one embodiment, the upper electrode is made of a material selected from the group consisting of metals of Ti, Pt, Ta, Ir, Sr, In, Sn, Au, Al, Fe, Cr, and Ni and oxides thereof.

According to at least one embodiment, the lower electrode is made of a material selected from the group consisting of metals of Ti, Pt, Ta, Ir, Sr, In, Sn, Au, Al, Fe, Cr, and Ni and oxides thereof.

According to at least one embodiment, the piezoelectric thin film has a film thickness of 1000 nm or more but 4000 nm or less.

According to at least one embodiment, the piezoelectric device is a micro electromechanical systems (MEMS) device.

According to at least one embodiment, the piezoelectric device is a piezoelectric actuating device.

According to at least one embodiment, the piezoelectric device is an optical device.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a graph showing a PZT-based piezoelectric thin film doped with Nb forming a perovskite crystal even though a composition ratio of Pb is less than 1 according to an embodiment of the invention.

FIG. 2 is a graph showing a high piezoelectric constant even though the composition ratio of Pb is less than 1, according to an embodiment of the invention, as compared to a PZT-based piezoelectric thin film according to the conventional art.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will be described in detail with reference to the accompanying drawings.

Embodiments of the invention relate to a commercially useful manufacturing method of an active piezoelectric film having availability for other piezoelectric devices and ferroelectric devices in addition to a micro electromechanical device and a ferroelectric random access memory, and uses thereof. Embodiments of the invention provide a novel thin film material made of a piezoelectric material, that is, Pb(Zr,Ti)O₃ (PZT), capable of being applied various fields for Si integration and significantly improving a piezoelectric effect and other ferroelectric properties.

In general, Pb(Zr,Ti)O₃ (PZT) has a perovskite crystal structure represented by ABO₃, wherein Pb is positioned at an A-site, and Zr and Ti are positioned at a B-site. In a deformed PZT-based piezoelectric ceramic material having piezoelectric and ferroelectric properties according to an embodiment of the invention, Pb is positioned at the A-site, Zr and Ti are mainly positioned at the B-site, and an element having a valence of +5 or +6 is positioned at the other site, such that even though a composition ratio of Pb is less than 1, a stable perovskite crystal structure is formed.

According to at least one embodiment, the PZT-based piezoelectric ceramic material has an ABO₃ perovskite crystal structure including a crystal lattice A site and B site and is represented by the following formula: Pbₓ(Zr_{y}Ti_{z})M_{1-y-z}O₃, wherein stoichiometries of Pb, Zr, and Ti need to satisfy the following Equations, respectively: 0.830≦x≦0.964, 0.43≦y≦0.55, and 0.43≦z≦0.55.

In detail, in a PZT-based piezoelectric ceramic material having the ABO₃ perovskite crystal structure, when stoichiometry x of Pb to be contained in the A-site is less than 1, more specifically, when the stoichiometry x is 0.964, in the case of PZT that is not doped, a pyrochlore crystal phase, which is a secondary phase, is partially contained, such that piezoelectric properties are significantly deteriorated. However, according to at least one embodiment, Zr and Ti present in the B-site are replaced with a metal element having a valence of +5 or +6, such that even though a ratio occupied by an A-site atom is less than 0.964, the perovskite crystal structure is stably and entirely formed. Therefore, the piezoelectric properties are not deteriorated. In the PZT-based piezoelectric ceramic material for obtaining the above-mentioned effect, the stoichiometries of Pb, Zr, and Ti in the formula Pbₓ(Zr_{y}Ti_{z})M_{1-y-z}O₃ need to satisfy the following Equation, respectively: 0.830≦x≦0.964, 0.43≦y≦0.55, and 0.43≦z≦0.55. In the case in which the stoichiometry x of Pb occupying the A-site is less than 0.830, it is impossible to form the perovskite structure, and in the case in which the stoichiometry x is more than 0.964, since this case is substantially equal to the case in which the stoichiometry x is 1, it is differentiate to distinguish this PZT-based piezoelectric ceramic material from a PZT-based piezoelectric ceramic materials prepared by adding an excessive amount of Pb without doping the metal element having a valence of +5 or +6.

According to at least one embodiment, M is selected from the group consisting of the metal elements having a valence of +5 or +6. More specifically, M is at least one selected from V, Nb, Sb, and Ta, which are metal elements having a valence of +5, and W, which is a metal element having a valence of +6.

According to at least one embodiment, in order to maintain the perovskite crystal structure in the case in which the composition ratio of Pb is less than 1, the A-site to be occupied by lead (Pb) in the ABO₃ structure needs to exist as a vacancy. Thus, among elements capable of being introduced in the B-site, the element having a valence of +5 or +6, such as Nb and Ta, as non-limiting examples, is doped, thereby inducing formation of the vacancy in the A-site while entirely maintaining an electric balance. Therefore, the perovskite crystal structure is maintained.

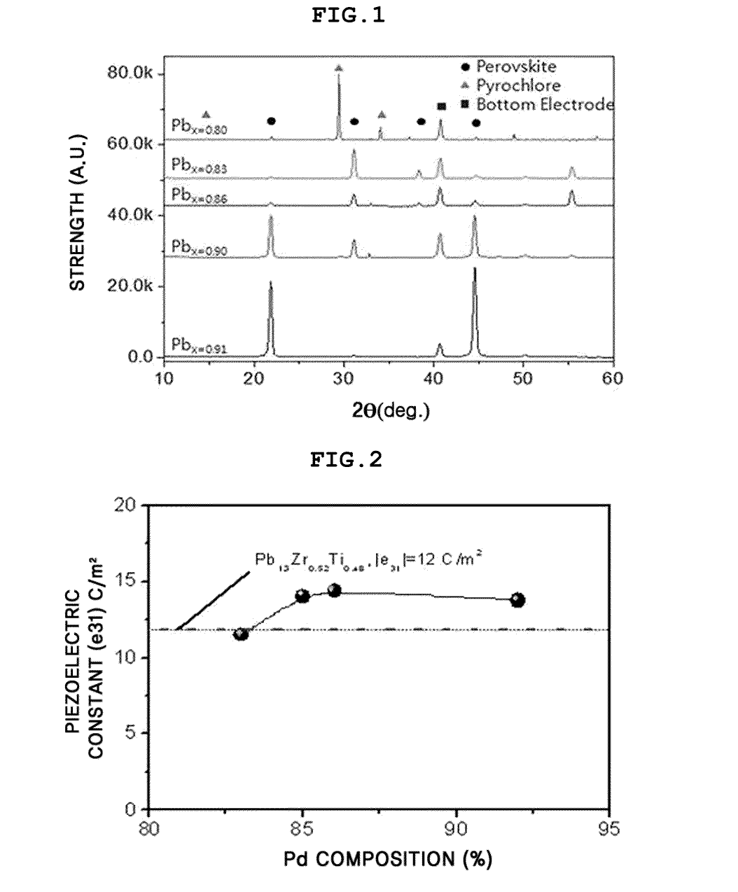

According to an embodiment of the invention, it is preferable that 12 to 14 at % of Nb is doped to replace the B-site elements. More preferably, 13 at % of Nb is doped to thereby replace the B-site elements. Referring to FIG. 1, it may be confirmed that at the time of doping 13 at % of Nb in a composition ratio of Pbₓ(Zr_{y}Ti_{z})Nb_{1-y-z}O₃, even though the composition ratio of Pb is less than 1, a stable perovskite crystal structure is formed. In this case, distortion of the perovskite crystal structure is caused by the added doped element and formation of Pb-vacancy, thereby making it possible to improve piezoelectric properties.

Meanwhile, FIG. 2 shows a piezoelectric constant value depending on the composition ratio of Pb when the composition ratio of Pb capable of being present in the A-site while not satisfying the stoichiometry is less than 1. Referring to FIG. 2, it may be appreciated that even in the case in which the composition ratio of Pb is less than 1, the piezoelectric properties are excellent as compared to an existing PZT-based piezoelectric film. When the stoichiometry of an atom to be contained in the A-site is 0.83 to 0.93, in the case of PZT that is not doped, the pyrochlore crystal phase, which is the secondary phase, is partially included, such that piezoelectric properties are deteriorated. However, according to at least one embodiment, even though a ratio stoichiometrically occupied by an A-site atom is decreased, the perovskite crystal structure is stably and entirely formed, such that the piezoelectric properties are not deteriorated. This result is obtained by doping 13% of Nb⁺⁵, and in the case in which the composition ratio of Pb is 0.83, an absolute piezoelectric constant value is 12C/m², similarly to the existing PZT-based piezoelectric thin film, and the absolute piezoelectric constant is maximally 15.1C/m² depending on the composition ratio of Pb. Generally, more excellent piezoelectric properties are exhibited than PZT in which 10 to 40% of Pb is excessively added in order to maximally suppress the pyrochlore crystal phase from being formed. A problem that the residual Pb from remaining in a form of a metal or oxide in the piezoelectric film due to the excessively added Pb only to deteriorate dielectric and electric properties are fundamentally suppressed. In the case of doping an element having a valence of +6, piezoelectric properties similar to those of the PZT-based piezoelectric film is exhibited even at a lower composition ratio of Pb.

In the case of utilizing Pb-vacancy formed in this composition and electric properties of the doped element as well as the piezoelectric properties as described above, it is possible to induce a spontaneous polarization property, for example. Thus, in the case of forming a local electric balance by controlling the Pb-vacancy or doped element in an interface with an electrode to induce internal-bias, spontaneous polarization properties that polarization directions are constantly arranged while the piezoelectric thin film is deposited due to gradient of an electric field as described above is exhibited.

Further, according to an embodiment of the invention, since Pb is not excessively added, an excessive residual Pb or PbO phase deteriorating properties is not formed, such that excellent electric, dielectric, and piezoelectric properties are exhibited. In addition, since it is possible to locally control the electric balance to constantly arrange an internal polarization direction simultaneously with depositing the piezoelectric film, degradation (due to a tendency to recover the polarization direction to an initial state thereof) by heat treatment after depositing the piezoelectric film is minimized.

According to at least one other embodiment, a piezoelectric device includes a substrate, a lower electrode formed on one surface of the substrate, a piezoelectric thin film formed on the lower electrode, and an upper electrode formed on the piezoelectric thin film, wherein the piezoelectric thin film is represented by the following formula: Pbₓ(Zr_{y}Ti_{z})M_{1-y-z}O₃, x, y, and z satisfying the following Equations, respectively: 0.830≦x≦0.964, 0.43≦y≦0.55, and 0.43≦z≦0.55, and M being an element having a valence of +5 or +6. When a composition ratio of Pb is set in a range of x as described above, and composition ratios of Zr, Ti, and M are set in ranges of y and z as described above, even though the composition ratio of Pb is less than 1, a perovskite crystal structure stably exhibiting piezoelectric properties are formed.

Hereinafter, a specific example of a preparation method of a piezoelectric ceramic material according to at least one embodiment will be described.

According to at least one embodiment, the piezoelectric ceramic material is prepared by a general method. In order to prepare the piezoelectric ceramic material according to at least one embodiment of the invention, oxide powders of components configuring the piezoelectric ceramic material according to at least one embodiment of the invention and supply sources of a B-site replacement element having a valence of +5 or +6 are weighed and mixed. Among the components configuring the piezoelectric ceramic material, Pb is supplied in a form of PbO, Zr is supplied in a form of ZrO₂, and Ti is supplied in a form of TiO₂. It is preferable that among supply sources of the B-site replacement elements, Nb, Zn, Ni, and Sb are supplied in forms of Nb₂O₅, ZnO, NiO, and Sb2O₃, respectively, to thereby be mixed.

According to at least one embodiment, it is preferable that slurry of the oxide powder and the supply source of the B-site replacement element having a valence of +5 or +6 are mixed by wet-ball milling, and it is preferable that at the time of ball milling, an ethanol solvent and high-purity 3Y-tetragonal zirconia polycrystalline (TZP) balls are used.

According to at least one embodiment, during the ball milling process, generally, grinding and mixing are simultaneously performed. In the case of mixing the components as described above, the oxides become in form of slurry.

Then, after sufficiently drying the powder slurry mixed as described above, the dried powder slurry is calcined in order to synthesize a crystal phase. In the case in which a calcination temperature is excessively high or a calcination time is excessively increased, binding force between particles is increased, such that it may be difficult to perform a grinding process to be performed later, and particle growth occurs, such that sintering properties are deteriorated. Therefore, it is preferable that calcination conditions are set in consideration the above-mentioned problems. The calcination temperature and calcination time are preferably 800 to 900° C. for 30 minutes or more, more preferably 2 to 5 hours.

Next, the calcined powder is finely ground again. It is preferable that the fine grinding is performed using ethanol and the 3Y-tetragonal zirconia polycrystalline (TZP) balls as described above. The calcined powder finely ground as described above becomes in a form of slurry. Thereafter, the finely ground powder slurry was formed in a desired shape and dried.

According to at least one embodiment, the formed product dried as described above is sintered. In the case in which a sintering temperature is excessively high or a sintering time is excessively increased, crystal grains grow to be large, such that the sintered product is mechanically weak. Further, as PbO is excessively volatilized, the composition is changed, such that piezoelectric properties are lost and dielectric loss is increased. Therefore, it is preferable that sintering conditions are set in consideration the above-mentioned problems.

According to at least one embodiment, it is preferable that the sintering is performed in the air at a temperature of 900 to 1200° C. for 30 minutes or more under atmospheric pressure. More preferably, the sintering is performed 1100 to 1200° C. for 1 to 4 hours. When the sintering is performed as described above, the piezoelectric ceramic material is obtained.

According to at least one embodiment, the piezoelectric device is manufactured using the piezoelectric ceramic material prepared as described above, and a manufacturing method of the piezoelectric device satisfying the present disclosure is not particularly limited, but any method may be used as long as it is generally used in the art to which the present disclosure pertains.

According to at least one embodiment, a piezoelectric thin film is formed by sputtering using the piezoelectric ceramic material prepared by the above-mentioned method as a target, and a piezoelectric device is manufactured using the piezoelectric thin film.

According to at least one embodiment, the piezoelectric device includes a substrate, a lower electrode formed on one surface of the substrate, a piezoelectric thin film formed on the lower electrode, and an upper electrode formed on the piezoelectric thin film.

A material of the substrate is not particularly limited, but in the manufacturing method of the piezoelectric thin film according to at least one embodiment of the invention, generally performed at 850° C. or less, a material that is not deformed or melted in a sintering process performed at 400° C. or more but 700° C. or less is preferable. To this end, for example, a semiconductor substrate made of silicon (Si) or tungsten (W), or a heat resistance stainless steel (SUS) substrate is preferably used, but ceramics such as zirconia, alumina, or silica are used. According to at least one embodiment, a combination of two or more materials as described above are used, or the materials are stacked to thereby form a multilayer structure. According to at least one embodiment, the materials are combined with a metal layer made of platinum and palladium to thereby be stacked.

According to at least one embodiment, the lower and upper electrodes are composed of conductive layers having a layer thickness of about 5 to 2000 nm, respectively. Although a material of the electrode is not particularly limited, any material may be used as long as it is generally used in the piezoelectric device. For example, examples of the material includes metals such as Ti, Pt, Ta, Ir, Sr, In, Sn, Au, Al, Fe, Cr, Ni, as non-limiting examples, and oxides thereof. Each of the lower and upper electrodes are formed using one thereof, or two or more thereof are stacked. The metal or oxide is formed by a sol-gel method, a sputtering method, and a deposition method, as non-limiting examples. Both of the lower and upper electrodes are patterned in desired shapes to thereby be used.

The piezoelectric device according to an embodiment of the invention is formed by preparing a substrate including a lower electrode formed on one surface thereof, forming a piezoelectric thin film on the lower electrode by a sputtering method using a piezoelectric ceramic material represented by the following formula Pbₓ(Zr_{y}Ti_{z})M_{1-y-z}O₃, and forming an upper electrode on the piezoelectric thin film, wherein x, y, and z satisfy the following Equations, respectively: 0.830≦x≦0.964, 0.43≦y≦0.55, and 0.43≦z≦0.55, and M is an element having a valence of +5 or +6.

According to an embodiment of the invention, the piezoelectric device is formed by the sputtering method. A single oxide target is used for the sputtering of the piezoelectric device. In detail, oxide powders weighed, so as to be suitable for each of the composition ratios are mixed, formed, and sintered at a high temperature, thereby preparing a piezoelectric ceramic sintered body, and the piezoelectric thin film is deposited by a radio-frequency sputtering method using the piezoelectric ceramic sintered body prepared as described above as a target.

According to at least one embodiment, a film thickness of the piezoelectric thin film is 1000 nm or more but 4000 nm or less. In the case in which a shape of the thin film is not flat, and thus, the film thickness does not have a single value, an average value of thicknesses between two electrodes substantially serving as a piezoelectric member at the time of being formed as the device is in the above-mentioned range. When the film thickness of the piezoelectric thin film is set to 1000 nm or less, displacement or force required for the piezoelectric device is obtained. When the film thickness is set to 4000 nm or less, densification of the device is expected.

A piezoelectric device belongs to a wide range of the present disclosure is not particularly limited, but includes a piezoelectric actuating device, an optical device including a geometry and spectrum- (or interference-) based device such as active and passive MEMS devices, a movable micro-lens array or movable micro-mirror array, a spectrum device changing a resonant cavity in an etalon structure to detune reflectivity of the device, a micro-pump and micro-valve based on cantilever geometry of a piezoelectric film, a high frequency applied ultrasonic transducer, microelectronics, an un-cooled IR radiation gyro-electric detector, and a non-volatile ferroelectric memory device, as non-limiting examples.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A lead zirconate titanate (PZT)-based piezoelectric ceramic material, comprising:
an ABO₃ perovskite crystal structure, and represented by the following formula:
Pbₓ(Zr_{y}Ti_{z})M_{1-y-z}O₃,
wherein x, y, and z satisfy the following Equations, respectively:
0.830≦x≦0.964,
0.43≦y≦0.55, and
0.43≦z≦0.55,
and M is a metal element having a valence of +5 or +6.

2. The PZT-based piezoelectric ceramic material of claim 1, wherein M is at least one metal element selected from the group consisting of V, Nb, Sb, Ta, and W.

3. The PZT-based piezoelectric ceramic material of claim 1, wherein M is Nb.

4. The PZT-based piezoelectric ceramic material of claim 1, wherein M is Ta.

5. The PZT-based piezoelectric ceramic material of claim 3, wherein 12 to 14 at % of Nb is doped therein.

6. A piezoelectric device, comprising:
a substrate;
a lower electrode formed on one surface of the substrate;
a piezoelectric thin film formed on the lower electrode; and
an upper electrode formed on the piezoelectric thin film,
wherein the piezoelectric thin film is manufactured using a PZT-based piezoelectric ceramic material having an ABO₃ perovskite crystal structure, and represented by the following formula: Pbₓ(Zr_{y}Ti_{z})M_{1-y-z}O₃, x, y, and z satisfying the following Equations, respectively: 0.830≦x≦0.964, 0.43≦y≦0.55, and 0.43≦z≦0.55, and M being an element having a valence of +5 or +6.

7. The piezoelectric device of claim 6, wherein M is at least one metal element selected from the group consisting of V, Nb, Sb, Ta, and W.

8. The piezoelectric device of claim 6, wherein M is Nb.

9. The piezoelectric device of claim 6, wherein M is Ta.

10. The piezoelectric device of claim 8, wherein 12 to 14 at % of Nb is doped therein.

11. The piezoelectric device of claim 6, wherein the piezoelectric thin film is formed by a radio-frequency sputtering method.

12. The piezoelectric device of claim 6, wherein the substrate is a semiconductor substrate made of silicon (Si) or tungsten (W), or a heat resistance stainless steel (SUS) substrate.

13. The piezoelectric device of claim 6, wherein the upper electrode is made of a material selected from the group consisting of metals of Ti, Pt, Ta, Ir, Sr, In, Sn, Au, Al, Fe, Cr, and Ni and oxides thereof.

14. The piezoelectric device of claim 6, wherein the lower electrode is made of a material selected from the group consisting of metals of Ti, Pt, Ta, Ir, Sr, In, Sn, Au, Al, Fe, Cr, and Ni and oxides thereof.

15. The piezoelectric device of claim 6, wherein the piezoelectric thin film has a film thickness of 1000 nm or more but 4000 nm or less.

16. The piezoelectric device of claim 6, wherein it is a micro electromechanical systems (MEMS) device.

17. The piezoelectric device of claim 6, wherein it is a piezoelectric actuating device.

18. The piezoelectric device of claim 6, wherein it is an optical device.
